(19) United States
(12) Patent Application Publication
(10) Pub. No.: US 2014/0353728 A1
(43) Pub. Date: Dec. 4, 2014

(54) METHOD AND APPARATUS FOR A REDUCED CAPACITANCE MIDDLE-OF-THE-LINE (MOL) NITRIDE STACK

(71) Applicant: GLOBALFOUNDRIES Inc., Grand Cayman (KY)

(72) Inventor: Garo J. Derderian, Saratoga Springs, NY (US)

(73) Assignee: GLOBALFOUNDRIES Inc., Grand Cayman (KY)

(21) Appl. No.: 13/903,694

(22) Filed: May 28, 2013

(51) Int. Cl. H01L 21/768; H01L 23/48

(52) U.S. Cl. CPC H01L 21/76802; H01L 23/481; H01L 21/76877
USPC 257/288; 438/666

(57) ABSTRACT

A method of capacitance reduction in a middle-of-the-line (MOL) nitride stack and a resulting device are disclosed. Embodiments include forming an oxide layer between one or more semiconductor devices on a wafer, the one or more semiconductor devices having source/drain junctions therebetween, forming a nitride layer over the one or more semiconductor devices and the oxide layer, forming a sacrificial oxide layer over the nitride layer, forming trenches through the oxide layer, the nitride layer, and the sacrificial oxide layer down to the source/drain junctions, forming a silicide in the trenches and on an upper surface of the sacrificial oxide layer, planarizing the silicide down to a point in the sacrificial oxide layer, and removing remaining sacrificial oxide to expose the nitride layer and a portion of the silicide protruding from an upper surface of the nitride layer.

### TECHNICAL FIELD

The present disclosure relates to a nitride stack in a middle-of-the-line (MOL) fabrication process. The present disclosure is particularly related to a new integration scheme for producing a thinner gate nitride.

### BACKGROUND

Nitride stacks are formed by opening contact holes in nitride and oxide layers covering one or more semiconductor devices on a silicon wafer. In a conventional MOL process, the nitride layer is formed to a thickness of approximately 40 nanometers (nm) and a thinner oxide layer is formed over the nitride layer to a thickness of approximately 10 nm. The oxide and nitride layers are then patterned to open contact holes down to the source/drain regions (hereinafter also referred to as “active regions”) of the semiconductor devices. In order to reduce the capacitance associated with the post gate (PG) nitride, a thinner nitride layer may be desirable. However, utilizing a thinner nitride layer in a conventional process flow is not feasible because gouging by a chemical mechanical polishing (CMP) process step may cause the semiconductor devices to be susceptible to short circuit failures.

FIG. 1A illustrates a nitride stack 101 formed on the substrate 103 following a conventional MOL process. As shown, the nitride stack 101 includes a sacrificial oxide layer 105 and a nitride layer 107 that are formed over a metal gate (MG) 109 and interlayer dielectric (ILD) 111 surrounding the metal gate. A silicide 113 is formed over the nitride stack 101 and in trenches 115 on opposite sides of the nitride stack 101 (the silicide 113 in the trenches 115 may be referred to as trench silicide (TS) hereinafter). FIG. 1B illustrates a subsequent stage through a conventional MOL process after the formation of contact areas (CA) in a dielectric oxide layer 117. In an intermediate step to expose the upper surface 119 of the nitride layer 107, the silicide 113 and the sacrificial oxide layer 105 (as well as a portion of the trench silicide (TS)) were removed by a CMP process. As previously mentioned, one method of reducing the nitride capacitance is to reduce the thickness of the nitride layer 107. However, if the nitride layer 107 is made thinner, the metal gates (MG) 109 may be susceptible to short circuit failures as a result of gouging the nitride layer 107 by the CMP process.

A need therefore exists for methodology enabling an integrated process for a thinner nitride layer that is less susceptible to short circuit failures caused by CMP gouging, and the resulting device.

### SUMMARY

An aspect of the present disclosure is a method for producing a reduced capacitance MOL nitride stack.

Another aspect of the present disclosure is a MOL nitride stack exhibiting reduced capacitance.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming an oxide layer between one or more semiconductor devices on a wafer, the one or more semiconductor devices having source/drain junctions therebetween, forming a nitride layer over the one or more semiconductor devices and the oxide layer, forming a sacrificial oxide layer over the nitride layer, forming trenches through the oxide layer, the nitride layer, and the sacrificial oxide layer down to the source/drain junctions, forming a silicide in the trenches and on an upper surface of the sacrificial oxide layer, planarizing the silicide down to a point in the sacrificial oxide layer, and removing remaining sacrificial oxide to expose the nitride layer and a portion of the silicide protruding from an upper surface of the nitride layer.

Aspects of the present disclosure include forming the nitride layer to a thickness of 10 nm to 30 nm. Further aspects include forming the sacrificial oxide layer to a thickness of 20 nm to 40 nm. Additional aspects include the source/drain regions being raised source/drain junctions. Further aspects include the silicide including tungsten (W). Additional aspects include planarizing the silicide by a W CMP process. Further aspects include the one or more semiconductor devices including metal gates. Further aspects include the remaining sacrificial oxide layer having a thickness from 1 nm to 20 nm. Additional aspects include forming a dielectric layer over the nitride layer and the protruding portions of the silicide, forming one or more contact holes through the dielectric layer down to the protruding portions of the silicide, and depositing a metal in the one or more contact holes. Further aspects include forming the one or more contact holes by reactive ion etching (RIE) with hydrofluoric (HF) acid.

Another aspect of the present disclosure is a device including one or more semiconductor devices on a wafer, the one or more devices having source/drain junctions, an oxide layer between the one or more semiconductor devices, a nitride layer over the one or more semiconductor devices and the oxide layer, trenches formed through the nitride layer and oxide layer down to the source/drain junctions, and a silicide filling the trenches and protruding above an upper surface of the nitride layer.

Aspects include the nitride layer having a thickness of 10 nm to 30 nm. Further aspects include the silicide protruding 1 nm to 20 nm above the upper surface of the nitride layer. Additional aspects include the source/drain junctions including raised source/drain junctions. Further aspects include the silicide being formed from W. Other aspects include a dielectric layer over the nitride layer, one or more contact holes through the dielectric layer over the protruding silicide, and a metal in the one or more contact holes. Additional aspects include the contact holes and the trenches having a conductive liner. Further aspects include the one or more semiconductor devices including metal gates.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A schematically illustrates a nitride stack according to a conventional MOL process;

FIG. 1B schematically illustrates a gate nitride following a conventional MOL process; and

FIGS. 2A through 2F schematically illustrate a process flow for forming a reduced capacitance MOL nitride stack, in accordance with an exemplary embodiment.

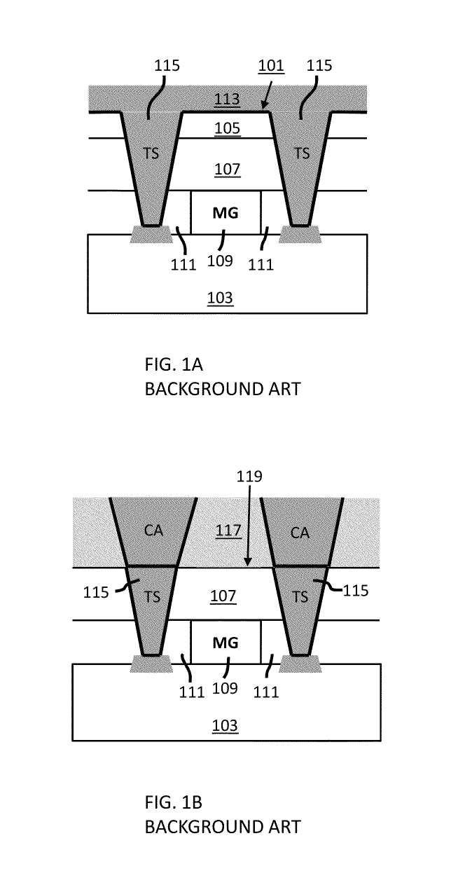

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of CMP gouging and short circuit failures attendant upon reducing gate nitride thickness to reduce capacitance. In accordance with embodiments of the present disclosure, a new integration scheme is utilized to enable a reduced capacitance MOL nitride stack.

Methodology in accordance with embodiments of the present disclosure includes utilization of a thicker sacrificial oxide layer and a thinner nitride layer. Additional aspects include the partial removal of the sacrificial oxide layer by a CMP process and utilization of an etching process to remove the remaining sacrificial oxide.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

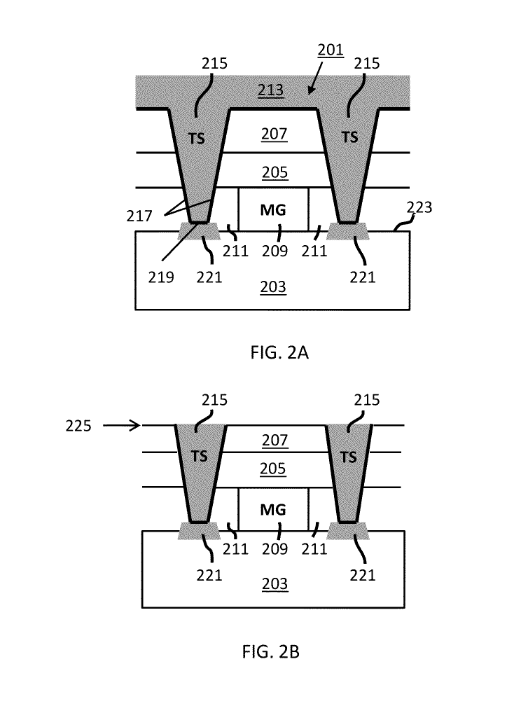

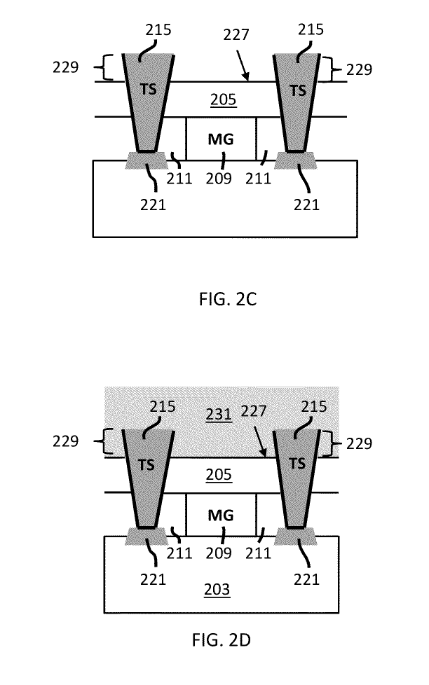

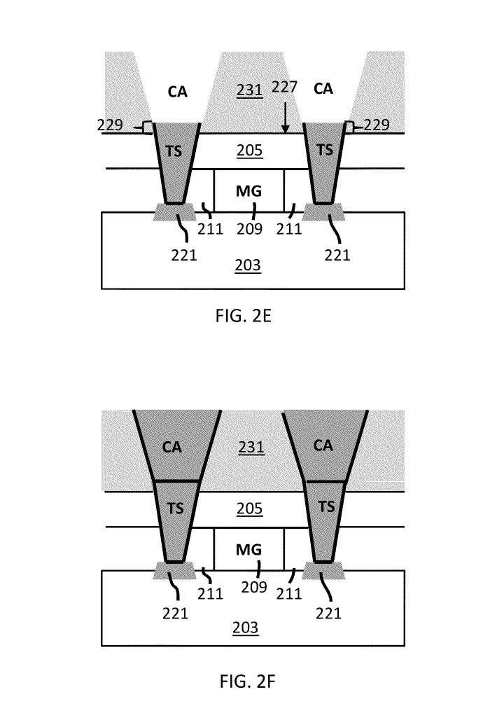

FIGS. 2A through 2F schematically illustrate various process steps for a reduced capacitance MOL nitride stack, in accordance with an exemplary embodiment of the present disclosure.

FIG. 2A illustrates a nitride stack 201 formed on a substrate 203 after MOL fabrication processes. As shown, the nitride stack 201 includes a nitride layer 205 and a sacrificial oxide layer 207. The sacrificial oxide layer 207 is formed over the nitride layer 205, which is formed over the metal gate (MG) 209 and the ILD 211 surrounding the metal gate (MG) 209. The nitride layer 205 may be formed of any dielectric material that does not etch with HF (e.g., silicon nitride or silicon oxy nitride) and may have a thickness from 10 nm to 30 nm. The sacrificial oxide layer 207 may have a thickness from 20 nm to 40 nm. The ILD 211 may be formed of silicon dioxide (SiO₂), silicon nitride (Si₃N₄), or some combination thereof.

As shown, a silicide 213 is formed over the nitride stack 201 and in the trenches 215 on opposite sides of the nitride stack 201 (the silicide in the trenches 215 may also be referred to as trench silicide (TS)). The silicide may be formed of titanium (Ti), titanium nitride (TiN) or W. If Ti or TiN is used for the silicide, the material lining the sidewalls 217 and the bottom surface 219 of the trenches 215 may include TiN. The relative proportion of Ti in the lining material may be greater at the bottom because of less accurate step coverage at lower depths.

As shown, the trenches 215 are formed down to the source/drain junctions 221 on opposite sides of the nitride stack 201. As indicated, the source/drain junctions 221 may be raised above the upper surface 223 of the substrate 203. The height of the raised source/drain junctions 221 above the substrate 203 may be as great as 5 nm less than the height of the metal gate (MG) 209 (i.e., gate height minus 5 nm). However, the present disclosure does not require that the source/drain junctions 221 be raised.

Adverting to FIG. 2B, a CMP process is used to remove the silicide 213 and an upper portion of the trench silicide (TS) and sacrificial oxide layer 207. As shown, the sacrificial oxide layer 207 is completely removed. Instead, the CMP process may stop at a stopping point 225 within the sacrificial oxide layer 207 (e.g., corresponding to a thickness of 10 nm). For example, the CMP process may stop halfway within the sacrificial oxide layer 207 (e.g., 15 nm if the thickness of the sacrificial oxide layer 207 was originally 30 nm). It is contemplated that any point within the sacrificial oxide layer 207 may correspond to a stopping point as long as some of the sacrificial oxide remains. For example, the stopping point 225 may be between 1 nm to 20 nm of the sacrificial oxide layer 207.

Adverting to FIG. 2C, the remaining sacrificial oxide of the sacrificial oxide layer 207 may be removed by an etching process (e.g., a wet etch using dilute HF or any other etching agent with similar chemistry to HF). As shown, after removal of the remaining sacrificial oxide, an upper surface 227 of the nitride layer 205 is exposed and protruding portions 229 of the trench silicide (TS) are left protruding from the upper surface 227 of the nitride layer 205.

Adverting to FIG. 2D, a dielectric oxide layer 231 is deposited on the upper surface 227 of the nitride layer 205 as well as on the protruding portions 229 of the trench silicide (TS). The dielectric oxide may include any oxide and may be formed by a plasma vapor deposition (PVD), chemical vapor deposition (CVD) (e.g., based on tetraethoxysilane (TEOS)), or a high density plasma (HDP) CVD process. The thickness of the dielectric oxide layer 231 may be approximately 50 nm.

Adverting to FIG. 2E, the dielectric oxide layer 231 is selectively etched to form one or more contact areas (CA). As shown, the contact areas (CA) may extend down to the protruding portions 229 of the trench silicide (TS). Ideally, the protruding sections 229 are not etched. However, the etching process may etch the protruding portions 229 to reduce their height above the upper surface 227 of the nitride layer 205 5 nm to 15 nm.

Adverting to FIG. 2F, a metal is deposited in the contact areas (CA) to establish contacts with the source/drain junctions 221 and/or the metal gates (MG) 209 (metal gate contacts are not shown for illustrative convenience). The metal may be deposited by a sputter process such that little, if any, of the nitride layer 205 is removed. The sputter process may however remove a portion (e.g., 10 nm) of the dielectric oxide layer 231.

The embodiments of the present disclosure can achieve several technical effects, including low nitride capacitance and a low rate of short circuit failures. The present disclosure enjoys industrial applicability in any of various MOL processes used to produce devices for various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming an oxide layer between one or more semiconductor devices on a wafer, the one or more semiconductor devices having source/drain junctions therebetween;
forming a nitride layer over the one or more semiconductor devices and the oxide layer;
forming a sacrificial oxide layer over the nitride layer;
forming trenches through the oxide layer, the nitride layer, and the sacrificial oxide layer down to the source/drain junctions;
forming a silicide in the trenches and on an upper surface of the sacrificial oxide layer;
planarizing the silicide down to a point in the sacrificial oxide layer; and
removing remaining sacrificial oxide to expose the nitride layer and a portion of the silicide protruding from an upper surface of the nitride layer.

2. The method according to claim 1, comprising forming the nitride layer to a thickness of 10 nanometers (nm) to 30 nm.

3. The method according to claim 1, comprising forming the sacrificial oxide layer to a thickness of 20 nm to 40 nm.

4. The method according to claim 1, wherein the source/drain junctions are raised source/drain junctions.

5. The method according to claim 1, wherein the silicide comprises tungsten (W).

6. The method according to claim 5, comprising planarizing the silicide by a W chemical-mechanical polishing (CMP) process.

7. The method according to claim 1, wherein the one or more semiconductor devices comprise metal gates.

8. The method according to claim 1, wherein the remaining sacrificial oxide has a thickness of 1 nm to 20 nm.

9. The method according to claim 1, further comprising:
forming a dielectric layer over the nitride layer and the protruding portions of the silicide;
forming one or more contact holes through the dielectric layer down to the protruding portions of the silicide; and
depositing a metal in the one or more contact holes.

10. The method according to claim 9, comprising forming the one or more contact holes by reactive ion etching (RIE) with hydrofluoric (HF) acid.

11. A device comprising:
one or more semiconductor devices on a wafer, the one or more devices having source/drain junctions;
an oxide layer between the one or more semiconductor devices;
a nitride layer over the one or more semiconductor devices and the oxide layer;
trenches formed through the nitride layer and oxide layer down to the source/drain junctions; and
a silicide filling the trenches and protruding above an upper surface of the nitride layer.

12. The device according to claim 11, wherein the nitride layer has a thickness of 10 nanometers (nm) to 30 nm.

13. The device according to claim 11, wherein the silicide protrudes 1 nm to 20 nm above the upper surface of the nitride layer.

14. The device according to claim 11, wherein the source/drain junctions comprise raised source/drain junctions.

15. The device according to claim 11, wherein the silicide comprises tungsten (W).

16. The device according to claim 11, further comprising:
a dielectric layer over the nitride layer;
one or more contact holes through the dielectric layer over the protruding silicide; and
a metal in the one or more contact holes.

17. The device according to claim 16, wherein the contact holes and the trenches have a conductive liner.

18. The device according to claim 16, wherein the one or more semiconductor devices comprise metal gates.

19. A method comprising:
forming an oxide layer between one or more semiconductor devices on a wafer, the one or more semiconductor devices having metal gates and raised source/drain junctions therebetween;
forming a nitride layer to a thickness of 10 nanometers (nm) to 30 nm over the one or more semiconductor devices and the oxide layer;
forming a sacrificial oxide layer to a thickness of 20 nm to 40 nm over the nitride layer;
forming trenches through the oxide layer, the nitride layer, and the sacrificial oxide layer down to the source/drain junctions;
forming a tungsten (W) silicide in the trenches and on an upper surface of the sacrificial oxide layer;
performing chemical-mechanical polishing (CMP) to a sacrificial oxide layer thickness of 20 nm to 40 nm;
removing remaining sacrificial oxide layer to expose the nitride layer and a portion of the silicide protruding from an upper surface of the nitride layer;
forming a dielectric layer over the nitride layer and the protruding portions of the silicide;
forming one or more contact holes through the dielectric layer down to the protruding portions of the silicide; and
depositing a metal in the one or more contact holes.

20. The method according to claim 19, comprising forming the contact holes by reactive ion etching (RIE).
